(19) United States
(12) Patent Application Publication
(10) Pub. No.: US 2025/0122892 A1
(43) Pub. Date: Apr. 17, 2025

(54) ELECTRONIC DEVICES AND CLEANING METHOD THEREOF AND DETERMINATION METHOD OF FAN STATUS DETERMINATION MODEL THEREOF

(71) Applicant: Acer Incorporated, New Taipei City (TW)

(72) Inventor: Pe-Yi LIN, New Taipei City (TW)

(73) Assignee: Acer Incorporated, New Taipei City (TW)

(21) Appl. No.: 18/769,582

(22) Filed: Jul. 11, 2024

(30) Foreign Application Priority Data
Oct. 11, 2023 (TW) 112138714

(51) Int. Cl. F04D 29/70; B08B 5/00; B08B 13/00; F04D 27/00; G01M 99/00; H05K 7/20

(52) U.S. Cl. CPC F04D 29/703; B08B 5/00; B08B 13/00; F04D 27/001; G01M 99/00; H05K 7/20209

(57) ABSTRACT

An electronic device includes a fan, an embedded controller, a fan status determination model and a processor. The Fan has an operating parameter. The embedded controller is configured to control the fan to operate with a control signal. The fan status determination model is configured to determine whether the fan is in a normal state or an abnormal state according to the control signal and operating parameter. The processor is configured to input the control signal and operating parameter into the fan status determination model. The embedded controller is further configured to control the fan to reversely rotate according to the abnormal state of the fan.

This application claims the benefit of Taiwan application Serial No. 112138714, filed Oct. 11, 2023, the subject matter of which is incorporated herein by reference.

### BACKGROUND OF THE INVENTION

### Field of the Invention

The invention relates in general to an electronic devices and a cleaning method thereof and a determination method of a fan status determination model thereof.

### Description of the Related Art

In order to dissipate heat, an electronic device is usually equipped with a fan. However, when there is dirt or dust on the fan, a cooling function of the fan will be reduced, and problems of, for example, an increased fan temperature and an increased noise will occur. Therefore, proposing a technology that may improve the aforementioned problems is one of the goals of those in this field.

### SUMMARY OF THE INVENTION

According to an embodiment of the present invention, an electronic device is provided. The electronic device includes a fan, an embedded controller (EC), a fan status determination model and a processor. The fan has an operating parameter. The embedded controller is configured to control the fan to operate with a control signal. The fan status determination model is configured to determine whether the fan is in a normal state or an abnormal state according to the control signal and the operating parameter. The processor is configured to input the control signal and the operating parameter to the fan status determination mode. The embedded controller is configured to control the fan to reverse based on the fan being in the abnormal state.

According to another embodiment of the present invention, a cleaning method for a fan includes the following steps: controlling the fan to operate with a control signal, wherein the fan has an operating parameter; inputting the control signal and the operating parameter to a fan status determination model; determining whether the fan is in a normal state or an abnormal state based on the control signal and the operating parameter by the fan status determination model; and controlling the fan to reverse based on the abnormal state of the fan.

According to another embodiment of the present invention, a fan status determination method for a fan status determination model includes the following steps: receiving a control signal and an operating parameter of a fan; determine a cleanliness status of the fan according to the control signal and the operating parameter; and output the cleanliness status.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 illustrates a functional block diagram of an electronic device according to an embodiment of the present invention;

FIG. 2 illustrates a training schematic diagram of the fan status determination model in FIG. 1;

FIG. 3 illustrates a functional block diagram of an electronic device according to another embodiment of the present invention; and

FIG. 4 illustrates a flow chart of the cleaning method of the electronic device in FIG. 1.

### DETAILED DESCRIPTION OF THE INVENTION

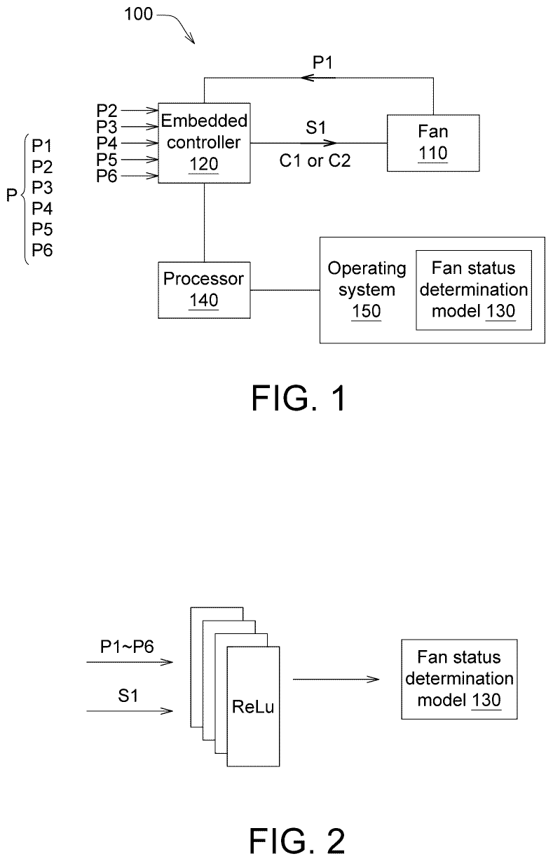

Referring to FIG. 1, FIG. 1 illustrates a functional block diagram of an electronic device 100 according to an embodiment of the present invention. The electronic device 100 is, for example, a desktop computer, a notebook computer, or other electronic device equipped with a fan.

As illustrated in FIG. 1, the electronic device 100 includes a fan 110, an embedded controller (EC) 120, a fan status determination model 130, a processor 140, and an operating system (OS) 150. The fan 110 has an operating parameter P. The embedded controller 120 is configured to control an operation of the fan 110 with a control signal S1. The fan status determination model 130 is configured to determine whether the fan 110 is in a normal state or an abnormal state according to the control signal S1 and the operating parameter P. The processor 140 is configured to input the control signal S1 and the operating parameter P into the fan status determination model 130. The embedded controller 120 is further configured to control a rotation of the fan 110 to clean the fan 110 based on the abnormal state of the fan 110.

In an embodiment, the control signal S1 and the operating parameter P are used as inputs to the fan status determination model 130, and accordingly the fan status determination model 130 outputs a determination result. When the determination result is 0, the fan 110 is in a normal state, while when the determination result is 1, the fan 110 is in an abnormal state. In the present embodiment, the “abnormal state” herein is, for example, the fan's cleanliness is low and therefore needs to be cleaned, and the “normal state” herein, for example, is that the fan is in a normal operating state (that is, the fan's cleanliness is as expected), so no cleaning is required.

In an embodiment, the operating parameter P includes, for example, at least one of an actual rotation speed P1 of the fan 110, an operating noise P2, a temperature P3, a usage frequency P4, an usage time P5, and a cleaning cycle P6. The control signal S1 is a pulse-width modulation (PWM). The embedded controller 120 is electrically connected to the fan 110, and outputs the control signal S1 to the fan 110 to control a rotation speed of the fan 110, a rotation direction of the fan 110, etc. The embedded controller 120 may detect or obtain at least one operating parameter from the fan 110, such as the actual rotation speed P1, the usage frequency P4 and/or the usage time

P5 of the fan 110, etc. The usage frequency P4 and the usage time P5 are, for example, the recorded time of the actual operation of the fan 110. In addition, the operating noise P2 is measured, for example, by a microphone (not illustrated) in the electronic device 100. When the operating noise P2 becomes louder, it indicates that the fan 110 may have too much dust or be blocked by dirt. The temperature P3 is obtained, for example, from a Basic Input/Output System (BIOS) of the electronic device 100. When the temperature P3 raises, it means that a friction loss of the fan 110 may increase due to dust. The cleaning cycle P6 is, for example, a time record of the user cleaning the fan 110, which may be recorded in the embedded controller 120 or the processor 130. In an embodiment, all operating parameters P may be transmitted to the embedded controller 120, and then transmitted to the processor 140 from the embedded controller 120. However, depending on the actual hardware design, one or some of all operating parameters may be transmitted to the processor 140 through the embedded controller 120, and the others of the operating parameters may be transmitted to the processor 140 not through the embedded controller 120.

The embedded controller 120 is configured to control the fan 110 to rotate around a first rotation direction with a first current value C1 based on the fact that the fan 110 being in the normal state; and control the fan 110 to rotate around a second rotation direction with a second current value C2 based on the abnormal state of the fan 110. The second current value C2 is smaller than the first current value C1. For example, the second current value is, for example, 3 ampere (A), and the first current value is, for example, 5 A. The first rotation direction is, for example, a preset rotation (for example, a forward rotation), and the second rotation direction is opposite to the first rotation direction, and the second rotation direction is also called a reverse rotation.

In the present embodiment, the fan status determination model 130 may be embedded in the operating system 150. The operating system 150 is a set of interrelated system software programs that supervises and controls computer operation, uses and executes hardware and software resources, and provides public services to organize user interaction. It is also the core and cornerstone of the computer system. The operating system needs to handle basic tasks such as managing and configuring memory, prioritizing system resource supply and demand, controlling input and output devices, operating networks, and managing file systems. The operating system also provides an operating interface for users to interact with the system.

The processor 140 is further configured to: after the electronic device 100 is booted up and loads the operating system 150, call (or load) the fan status determination model 130 to determine whether the fan needs to be cleaned. If so, the cleaning method for the fan 110 is activated.

The fan status determination model 130 may perform a determination method, such as a determination method for the fan cleanliness. The determination method may include: receiving the control signal S1 and the operation parameter P of the fan 110 (that is, the control signal S1 and the operation parameter P are the inputs of the fan status determination model 130); determining the cleanliness of the fan 110 according to the control signal S1 and the operation parameter P; and output the cleanliness status (in other words, the cleanliness status is the output of the fan status determination model 130) to the embedded controller 120 or the processor 140. The “cleanliness status” here is, for example, one of the aforementioned “abnormal state” and “normal state”.

The fan status determination model 130 is obtained by using the ReLU (Rectified Linear Unit) excitation function in Deep Neural Networks (DNN). However, the embodiment of the present invention does not limit the acquisition technology of the fan status determination model 130.

Referring to FIG. 2, FIG. 2 illustrates a training schematic diagram of the fan status determination model 130 in FIG. 1. In the process of training the fan status determination model 130, the ReLU linear regression model is used to train the machine learning algorithm, using the control signal S1 and at least one of all operating parameters as input variables (i.e., X), and the fan cleanliness status (normal status is defined as 0, and the abnormal state is defined as 1) as the output variable (i.e., Y). The linear regression model will learn a linear function to map the input variables to the output variables, thereby generating or training the fan status determination model 130. In addition, during the training phase, using Scikit-learn function library, 80% of the N samples are used as a training set to generate the fan status determination model 130, and the remaining 20% of the N samples may be used as an accuracy validation set to verify the fan status determination model 130. The embodiment of the present invention does not limit the value of N. It has been verified that the accuracy of the cleaning method using the fan status determination model 130 may reach more than 97%.

The use of excitation functions in neural networks mainly uses nonlinear equations to solve nonlinear problems. If the activation function is not used, the neural network performs the combination operation in a linear manner, because a hidden layer and an output layer both take the results of the upper layer as the inputs, calculate it by a linear combination, and take the calculation result as the output of this layer, so that a relationship between the output and the input only is a linear relationship. In reality, all problems are nonlinear problems. Therefore, if a nonlinear excitation function is not used, the model trained by the neural network will lose its meaning. The ReLU, also called as modified linear unit, is an activation function commonly used in neural networks, and it usually refers to nonlinear functions represented by a ramp function and their variants.

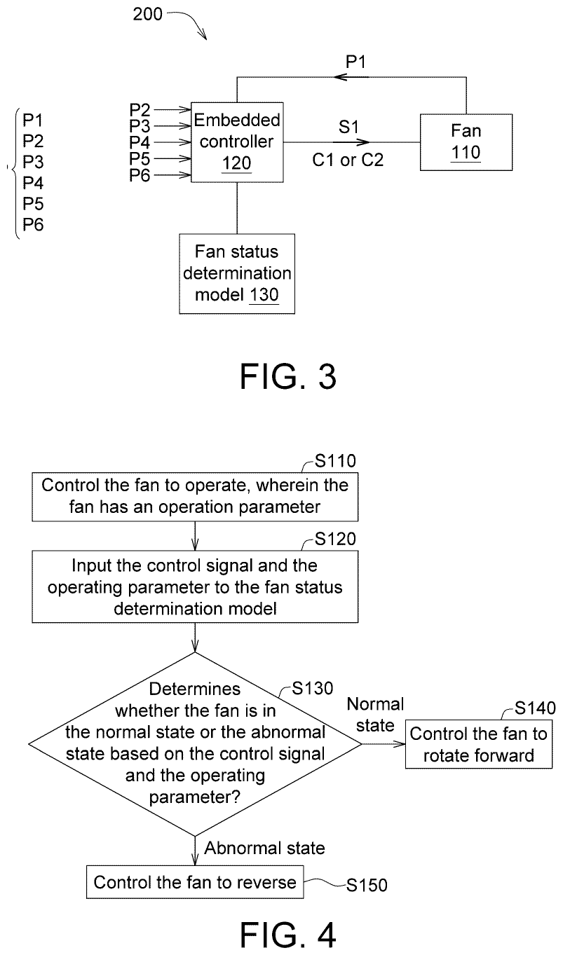

Referring to FIG. 3, FIG. 3 illustrates a functional block diagram of an electronic device 200 according to another embodiment of the present invention. The electronic device 200 includes the fan 110, the embedded controller 120 and the fan status determination model 130. The fan 110 has the operating parameter P. The embedded controller 120 is configured to control the fan 110 to operate with the control signal S1. The fan status determination model 130 is configured to determine whether the fan 110 is in the normal state or the abnormal state according to the control signal S1 and the operating parameter P. The electronic device 200 of the embodiment of the present invention has the same or similar technical features as the aforementioned electronic device 100, and one of the differences is that the fan status determination model 130 may be called or loaded by the embedded controller 120. The embedded controller 120 may execute the cleaning method without waiting to enter the operating system stage.

As shown in FIG. 3, the embedded controller 120 is configured to: input the control signal S1 and the operating parameter P to the fan status determination model 130, and control the fan 110 to reverse to clean the fan 110 according to the abnormal state of the fan 110. In the present embodiment, the fan status determination model 130 is, for example, firmware, which may be stored in a read-only memory (ROM).

Referring to FIG. 4, FIG. 4 illustrates a flow chart of the cleaning method of the electronic device 100 in FIG. 1.

In step S110, the embedded controller 120 control the fan 110 to operate with the control signal S1, wherein the fan 110 has the operation parameter P.

In step S120, the processor 140 inputs the control signal S1 and the operating parameter P to the fan status determination model 130.

In step S130, the fan status determination model 130 determines whether the fan 120 is in the normal state or the abnormal state according to the control signal S1 and the operating parameter P. If the fan 120 is in the normal state, the process proceeds to step S140; if the fan 120 is in the abnormal state, the process proceeds to step S150.

In step S140, the embedded controller 120 may maintain the current operation of the fan 110 or control the fan 110 to rotate forward based on the fact that the fan 120 being in the normal state which indicates that the fan 110 does not need to be cleaned.

In step S150, the embedded controller 120 controls the fan 110 to reverse to clean the fan 110 based on the fact that the fan 120 being in the abnormal state which indicates that the fan 110 needs to be cleaned.

In summary, the embodiments of the present invention propose an electronic device, a cleaning method thereof and an fan status determination model thereof, which may automatically or actively determine the cleanliness of the fan. When the cleanliness of the fan is low and needs to be cleaned, the embedded controller controls the fan to reverse to clean the fan.

While the invention has been described by way of example and in terms of the preferred embodiment(s), it is to be understood that the invention is not limited thereto. Based on the technical features embodiments of the present invention, a person ordinarily skilled in the art will be able to make various modifications and similar arrangements and procedures without breaching the spirit and scope of protection of the invention. Therefore, the 10 scope of protection of the present invention should be accorded with what is defined in the appended claims.

What is claimed is:

1. An electronic device, comprising:
a fan having an operating parameter;
an embedded controller (EC), configured to:
control the fan to operate with a control signal;
a fan status determination model, configured to:
determine whether the fan is in a normal state or an abnormal state according to the control signal and the operating parameter;
a processor, configured to:
input the control signal and the operating parameter to the fan status determination mode;
wherein the embedded controller is configured to:
control the fan to reverse based on the fan being in the abnormal state.

2. The electronic device as claimed in claim 1, wherein the fan status determination model is embedded in an operating system (OS); the processor is further configured to:
after the electronic device is booted up and loads the operating system, call the fan status determination model.

3. The electronic device as claimed in claim 1, wherein the operating parameters comprises at least one of an actual rotation speed of the fan, an operating noise of the fan, a temperature of the fan, a usage frequency of the fan, a usage time of the fan and a cleaning cycle of the fan.

4. The electronic device as claimed in claim 1, wherein the control signal is a pulse-width modulation (PWM).

5. The electronic device as claimed in claim 1, wherein the fan status determination model is obtained by using a ReLU (Rectified Linear Unit) excitation function in a deep neural network (DNN).

6. The electronic device as claimed in claim 1, wherein the embedded controller is further configured to:
control the fan to rotate around a first rotation direction with a first current value based on the fact that the fan is in the normal state; and
control the fan to rotate around a second rotation direction with a second current value based on the fact that the fan is in the abnormal state;
wherein the second current value is smaller than the first current value, and the second rotation direction is opposite to the first rotation direction.

7. A cleaning method for a fan, and comprising:
controlling the fan to operate with a control signal, wherein the fan has an operating parameter;
inputting the control signal and the operating parameter to a fan status determination model;
determining whether the fan is in a normal state or an abnormal state based on the control signal and the operating parameter by the fan status determination model; and
controlling the fan to reverse based on the abnormal state of the fan.

8. The cleaning method as claimed in claim 7, wherein the fan status determination model is embedded in an operating system (OS); the cleaning method further comprises:
after the electronic device is booted up and loads the operating system, calling the fan status determination model.

9. The cleaning method as claimed in claim 7, wherein step of inputting the control signal and the operating parameter to the fan status determination mode comprises:
inputting the control signal and at least one of an actual rotation speed of the fan, an operating noise of the fan, a temperature of the fan, a usage frequency of the fan, a usage time of the fan and a cleaning cycle of the fan to the fan status determination model.

10. The cleaning method as claimed in claim 7, wherein step of controlling the fan to operate with the control signal comprises:
controlling the fan to operate with a pulse-width modulation.

11. The cleaning method as claimed in claim 7, further comprising:
controlling the fan to rotate around a first rotation direction with a first current value based on the fact that the fan is in the normal state; and
controlling the fan to rotate around a second rotation direction with a second current value based on the fact that the fan is in the abnormal state.

12. A fan status determination method of a fan status determination model, comprising:
receiving a control signal and an operating parameter of a fan;
determine a cleanliness status of the fan according to the control signal and the operating parameter; and
output the cleanliness status.
